(19) United States
(12) Patent Application Publication
(10) Pub. No.: US 2026/0229273 A1
(43) Pub. Date: Aug. 6, 2026

(54) ACCESS LINE DIVISION FOR MEMORY DEVICES

(71) Applicant: Micron Technology, Inc., Boise, ID (US)

(72) Inventor: Simon J. Lovett, Nampa, ID (US)

(21) Appl. No.: 19/444,947

(22) Filed: Jan. 9, 2026

Related U.S. Application Data
(60) Provisional application No. 63/752,507, filed on Jan. 31, 2025.

(51) Int. Cl. G11C 11/406; G11C 11/408; G11C 11/4091; G11C 11/4093

(52) U.S. Cl. CPC G11C 11/40615; G11C 11/4085; G11C 11/4091; G11C 11/4093

(57) ABSTRACT

Methods, systems, and devices for access line division for memory devices are described. A memory array may include transistors that divide access lines (e.g., digit lines) into first portions associated with a first address range (e.g., a first range of word lines) and second portions associated with a second address range (e.g., a second range of word lines), such as along respective lengths of the access lines. When a memory cell in the first address range is accessed, transistors coupled with first access lines may be activated while transistors coupled with second access lines may isolate portions of the second access lines in the second address range. When a memory cell in the second address range is accessed, transistors coupled with the second access lines may be activated while transistors coupled with the first access lines may isolate portions of the first digit lines in the first address range.

### CROSS REFERENCE

The present Application for Patent claims priority to U.S. Patent Application No. 63/752,507 by Lovett, entitled “ACCESS LINE DIVISION FOR MEMORY DEVICES,” filed January 31, 2025, which is assigned to the assignee hereof, and which is expressly incorporated by reference in its entirety herein.

### TECHNICAL FIELD

The following relates to one or more systems for memory, including access line division for memory devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports access line division for memory devices in accordance with examples as disclosed herein.

FIGS. 2 and 3 show examples of circuits that support access line division for memory devices in accordance with examples as disclosed herein.

FIG. 4 shows a block diagram of a memory device that supports access line division for memory devices in accordance with examples as disclosed herein.

FIG. 5 shows a flowchart illustrating a method that supports access line division for memory devices in accordance with examples as disclosed herein.

### DETAILED DESCRIPTION

As the density of memory cells in a memory device increases, the amount of power used to perform access operations (e.g., read, write, refresh) at the memory cells may increase. Memory cells may be accessed based on selecting a target word line, selecting a target digit line, and sensing a state of the memory cell at a sense amplifier coupled with the target digit line. In some memory systems, the target digit line may be coupled with multiple rows (e.g., hundreds of rows, over a thousand rows) of unselected word lines. A length of the target digit line may contribute to a capacitance (e.g., intrinsic capacitance) of the digit line. In some examples, a significant portion (e.g., over half) of the power used to perform the access operations at a target memory cell may be caused by charging the target digit line (e.g., to select the memory cell), which may be a function of digit line capacitance.

In accordance with aspects as disclosed herein, a memory array may include transistors (e.g., multiplexors, pass gates) that divide (e.g., bisect) digit lines of the memory array into a first address range (e.g., associated with a first range of rows, associated with a first range of word lines) and a second address range (e.g., associated with a second range of rows, associated with a second range of word lines), which may be associated with a division along a length of each digit line. Dividing the digit lines may reduce the effective capacitance of accessing at least a portion of the digit lines, thereby reducing an amount of power used to access at least some memory cells. In some implementations, such digit lines may include a set of even digit lines and a set of odd digit lines, for which a respective even digit line may be adjacent to a respective odd digit line (e.g., in accordance with an alternating pattern of even and odd digit lines), and for which a respective sense amplifier coupled with an even digit line may be located on an opposite end of a respective sense amplifier coupled with an odd digit line. When a memory cell in the first address range is accessed, transistors coupled with the even digit lines may be activated (e.g., coupling portions of the even digit lines) whereas transistors coupled with the odd digit lines may be deactivated (e.g., isolating portions of the odd digit lines). When a memory cell in the second address range is accessed, transistors coupled with the odd digit lines may be activated (e.g., coupling portions of the odd digit lines) whereas transistors coupled with the even digit lines may be deactivated (e.g., isolating portions of the even digit lines). In some examples, while a respective transistor on a digit line is deactivated, a second transistor coupled with the same digit line may be activated to support biasing a portion of the digit line with a voltage (e.g., to prevent a portion of the digit line that is isolated from a sense amplifier from being in an electrically floating condition). By reducing digit line capacitance for accessing at least some memory cells, the described techniques may support reduced power consumption, reduced latency, or both for accessing a memory array.

In addition to applicability in memory systems as described herein, techniques for access line division for memory devices may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing an amount of power used to access memory cells, or reduce latency associated with accessing memory cells, or both, which may enable reduced power consumption, longer operational duration for a given battery charge, improved response times, and improved data throughput or access speeds, among other benefits.

Features of the disclosure are illustrated and described in the context of memory devices and related circuitry. Features of the disclosure are further illustrated and described in the context of circuits and flowcharts.

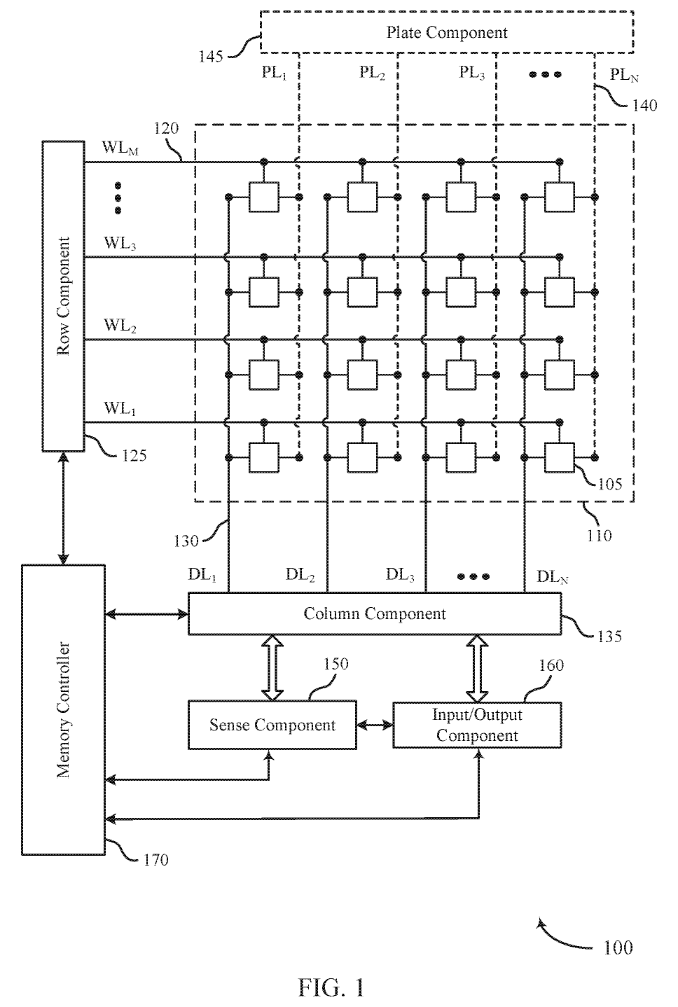

FIG. 1 shows an example of a memory device 100 that supports access line division for memory devices in accordance with examples as disclosed herein. The memory device 100 may be referred to as a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100, where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component), and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 of the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row components 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

In some memory architectures, accessing a memory cell 105 may degrade or destroy a stored logic state, and rewrite or refresh operations may be performed to return the stored logic state to memory cell 105. In DRAM or FeRAM, for example, a capacitor of a memory cell 105 may be partially or completely discharged or depolarized during a sense operation, thereby corrupting the logic state that was stored in the memory cell 105. Thus, in some examples, the logic state stored in a memory cell 105 may be rewritten after an access operation. Further, activating a single word line 120, digit line 130, or plate line 140 may result in the discharge of all memory cells 105 coupled with the activated word line 120, digit line 130, or plate line 140. Thus, several or all memory cells 105 coupled with a word line 120, digit line 130, or plate line 140 associated with an access operation (e.g., all cells of an accessed row, all cells of an accessed column) may be rewritten after an access operation, or in accordance with a periodic interval, or both.

In some examples, reading a memory cell 105 may be non-destructive. That is, the logic state of the memory cell 105 may not need to be rewritten after the memory cell 105 is read. However, in some examples, refreshing the logic state of the memory cell 105 may be used to mitigate more gradual degradations of the state stored in the memory cell 105. For example, the logic state stored by a memory cell 105 may be refreshed at periodic intervals by applying an appropriate write, rewrite, or refresh bias to maintain the stored logic state. Refreshing the memory cell 105 may reduce or eliminate data corruption due to a degradation of stored state over time.

In some examples, capacitance of a digit line 130 (e.g., intrinsic capacitance) may be a significant contribution to power consumption, latency, or both when accessing memory cells 105 of an array 110. For example, a substantial amount of power consumption associated with refreshing an array 110 (e.g., more than half of such power consumption) may be associated with digit line charging current, which may be a function of capacitance of digit lines 130. Capacitance of digit lines 130 may be a function of the length of the digit lines 130, which may be associated with a quantity of rows (e.g., word lines 120) that intersect the digit lines 130. As arrays 110 become larger, more dense, or both, a quantity of rows that intersect digit lines 130 may increase, which thus may be associated with power consumption, latency, or other concerns.

In accordance with aspects as disclosed herein, a memory array 110 may include transistors (e.g., multiplexors, pass gates) that divide (e.g., bisect) each of the digit lines 130 of the memory array 110 into a first address range (e.g., associated with a first range of word lines 120) and a second address range (e.g., associated with a second range of word lines 120), which may be associated with a division along a length of each digit line 130. Dividing the digit lines 130 may reduce the effective capacitance of accessing at least a portion of the digit lines 130, thereby reducing an amount of power used to access at least some memory cells 105. In some implementations, such digit lines 130 may include a set of even digit lines 130 and a set of odd digit lines 130, for which a respective even digit line 130 may be adjacent to a respective odd digit line 130 (e.g., in accordance with an alternating pattern of even and odd digit lines 130), and for which a respective sense amplifier (e.g., of a sense component 150) coupled with an even digit line 130 may be located on an opposite end of a respective sense amplifier coupled with an odd digit line 130. When a memory cell 105 in the first address range is accessed, transistors coupled with the even digit lines may be activated (e.g., coupling portions of the even digit lines 130) whereas transistors coupled with the odd digit lines may be deactivated (e.g., isolating portions of the odd digit lines 130). When a memory cell 105 in the second address range is accessed, transistors coupled with the odd digit lines 130 may be activated (e.g., coupling portions of the odd digit lines 130) whereas transistors coupled with the even digit lines 130 may be deactivated (e.g., isolating portions of the even digit lines 130). In some examples, while a respective transistor on a digit line 130 is deactivated, a second transistor coupled with the same digit line 130 may be activated to support biasing a portion of the digit line 130 with a voltage (e.g., to prevent a portion of the digit line 130 that is isolated from a sense amplifier from being in an electrically floating condition).

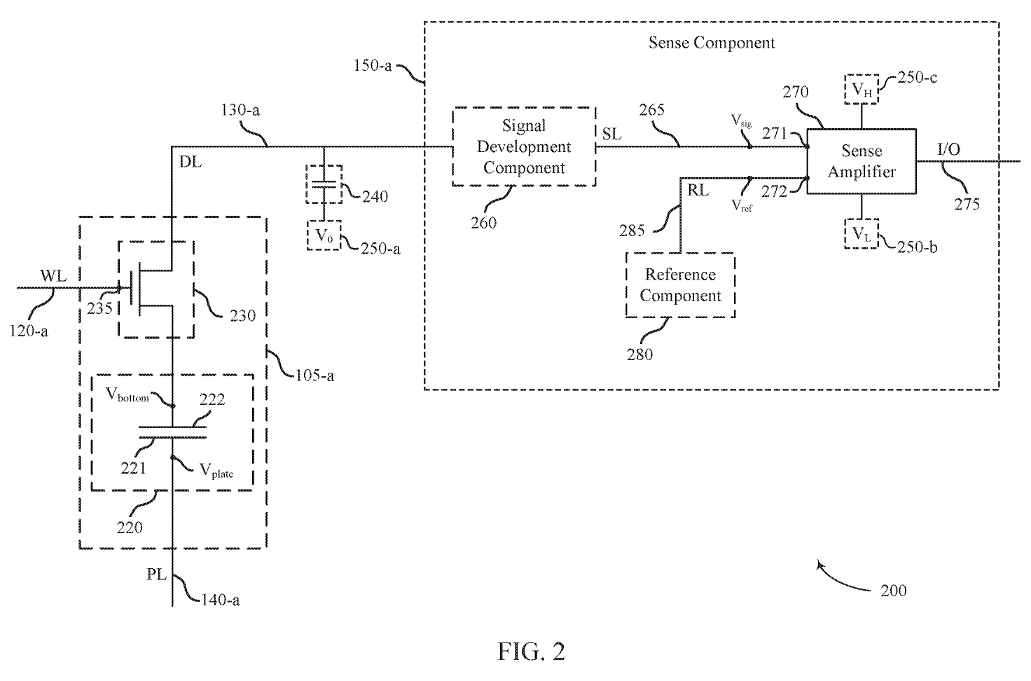

FIG. 2 shows an example of a circuit 200 that supports access line division for memory devices in accordance with examples as disclosed herein. The circuit 200 includes a memory cell 105-a and a sense component 150-a, which may be examples of the respective components as described with reference to FIG. 1. Circuit 200 also includes a word line 120-a, a digit line 130-a, and a plate line 140-a, which may be examples of the respective access lines described with reference to FIG. 1. In various examples, the plate line 140-a may be illustrative of an independently-addressable plate line 140-a, or a common plate node (e.g., of an array 110 that includes the memory cell 105-a). In some memory architectures (e.g., DRAM), the plate line 140-a may be an example of a ground node, such as Vss. In some other memory architectures (e.g., FeRAM), the plate line 140-a may be biased to different voltage levels during different portions of operations performed using the memory cell 105-a.

The memory cell 105-a may include a logic storage component (e.g., a memory element, a storage element, a memory storage element), such as a capacitor 220 that has a first plate, cell plate 221, and a second plate, cell bottom 222. The cell plate 221 and the cell bottom 222 may be capacitively coupled through a dielectric material positioned between them (e.g., in a DRAM application), or capacitively coupled through a ferroelectric material positioned between them (e.g., in a FeRAM application). The cell plate 221 may be associated with a voltage Vₚₗₐₜₑ, and cell bottom 222 may be associated with a voltage V_{bottom}, as illustrated in the circuit 200. The cell plate 221 may be accessed via the plate line 140-a and cell bottom 222 may be accessed via the digit line 130-a. As described herein, various logic states may be stored by charging, discharging, or polarizing the capacitor 220.

The capacitor 220 may be electrically connected with the digit line 130-a, and the stored logic state of the capacitor 220 may be read or sensed by operating various elements represented in circuit 200. For example, the memory cell 105-a may also include a cell selection component 230 which, in some examples, may be referred to as a switching component or a selector device coupled with or between an access line (e.g., the digit line 130-a) and the capacitor 220. In some examples, a cell selection component 230 may be considered to be outside the illustrative boundary of the memory cell 105-a, and the cell selection component 230 may be referred to as a switching component or selector device coupled with or between an access line (e.g., the digit line 130-a) and the memory cell 105-a.

The capacitor 220 may be selectively coupled with the digit line 130-a when the cell selection component 230 is activated (e.g., by way of an activating logical signal), and the capacitor 220 can be selectively isolated from the digit line 130-a when the cell selection component 230 is deactivated (e.g., by way of a deactivating logical signal). A logical signal or other selection signal or voltage may be applied to a control node 235 of the cell selection component 230 (e.g., via the word line 120-a). In other words, the cell selection component 230 may be configured to selectively couple or decouple the capacitor 220 and the digit line 130-a based on a logical signal or voltage applied via the word line 120-a to the control node 235.

Activating the cell selection component 230 may be referred to as selecting or activating the memory cell 105-a, and deactivating the cell selection component 230 may be referred to as deselecting or deactivating the memory cell 105-a. In some examples, the cell selection component 230 is a transistor and its operation may be controlled by applying an activation voltage to the transistor gate (e.g., a control or selection node or terminal). The voltage for activating the transistor (e.g., the voltage between the transistor gate terminal and the transistor source terminal) may be a voltage greater than the threshold voltage magnitude of the transistor. In some examples, activating the cell selection component 230 may be referred to as coupling the memory cell 105-a with the digit line 130-a.

Biasing the plate line 140-a or the digit line 130-a may result in a voltage difference (e.g., the voltage of the digit line 130-a minus the voltage of the plate line 140-a) across the capacitor 220. The voltage difference may accompany a change in the charge stored by the capacitor 220 (e.g., due to charge sharing between the capacitor 220 and the digit line 130-a, due to charge sharing between the capacitor 220 and the plate line 140-a), and the magnitude of the change in stored charge may depend on the initial state of the capacitor 220 (e.g., whether the initial charge or logic state stored a logic 1 or a logic 0).

The digit line 130-a may be coupled with additional memory cells 105 (not shown), and the digit line 130-a may have properties that result in a non-negligible intrinsic capacitance 240 (e.g., on the order of picofarads (pF)), which may couple the digit line 130-a with a voltage source 250-a. The voltage source 250-a may represent a common ground or virtual ground voltage, or the voltage of an adjacent access line of the circuit 200 (not shown). Although illustrated as a separate element in FIG. 2, the intrinsic capacitance 240 may be associated with properties distributed throughout the digit line 130-a.

The sense component 150-a may include a signal development component 260 and a sense amplifier 270 coupled with the signal development component 260 via a signal line 265. In various examples, the signal development component 260 may include circuitry configured to amplify or otherwise convert signals of the digit line 130-a prior to a logic state detection operation (e.g., by the sense amplifier 270). The signal development component 260 may include, for example, a transistor, an amplifier, a cascode, or any other circuitry configured to develop a signal for sensing a logic state stored by the memory cell 105-a. In some examples, the signal development component 260 may include a charge transfer sensing amplifier, which may include one or more transistors in a cascode or voltage control configuration. In some other examples, a signal development component 260 may be omitted.

Although the digit line 130-a and the signal line 265 are identified as separate lines, the digit line 130-a, the signal line 265, and any other lines connecting a memory cell 105 with a sense amplifier 270 may be referred to as a single access line (e.g., of or associated with the memory cell 105). Constituent portions of such an access line may be identified separately for the purposes of illustrating intervening components and intervening signals in various example configurations.

The sense amplifier 270 may include a first node 271 and a second node 272 which, in some examples, may be coupled with different access lines of a circuit (e.g., a signal line 265 and a reference line 285 of the circuit 200, respectively) or, in other examples, may be coupled with a common access line of a different circuit (not shown). In some examples, the first node 271 may be referred to as a signal node, and the second node 272 may be referred to as a reference node. However, other configurations of access lines or reference lines may be used to support the techniques described herein.

The sense amplifier 270 may include various transistors or amplifiers to detect, convert, or amplify a difference in signals, which may be referred to as latching. For example, the sense amplifier 270 may include circuit elements that receive and compare a sense signal voltage (e.g., V_{sig}, of the signal line 265) at a first node 271 with a reference signal voltage (e.g., V_{ref}, of a reference line 285) at a second node 272. A voltage of the first node 271 may be based on accessing the memory cell 105-a, such as a voltage based at least in part on a charge transfer of the capacitor 220 while the cell selection component 230 is activated. In some examples, a voltage of the second node 272 may be provided by a reference component 280 (e.g., a reference voltage source). In some other examples, a reference voltage may be provided, for example, by accessing the memory cell 105-a to generate the reference voltage (e.g., in a self-referencing access operation), or by accessing a second memory cell 105 (e.g., a complementary memory cell 105) to generate the reference voltage (e.g., in a paired or complementary memory cell access operation), in which case at least a portion of the reference component 280 may be included as part of a signal development component 260, or at least a portion of the reference component 280 may be omitted. An output of the sense amplifier 270 may be driven to a relatively higher voltage (e.g., a positive voltage) or a relatively lower voltage (e.g., a negative voltage, a ground voltage) based on the comparison at the sense amplifier 270.

The sense amplifier 270 may output a detected logic state via one or more I/0 lines 275 based on a comparison of signals at the first node 271 and the second node 272. For example, if the first node 271 has a lower voltage than the second node 272, an output of the sense amplifier 270 may be driven to a relatively lower voltage of a first sense amplifier voltage source 250-b (e.g., a voltage of V_{L,} which may be a ground voltage substantially equal to V₀ or a negative voltage). If the first node 271 has a higher voltage than the second node 272, an output of the sense amplifier 270 may be driven to the voltage of a second sense amplifier voltage source 250-c (e.g., a voltage of V_{H}). The sense component 150-a may latch the output of the sense amplifier 270 to determine the logic state stored in the memory cell 105-a (e.g., latching or determining a logic 0 if the first node 271 has a lower voltage than the second node 272, latching or determining a logic 1 if the first node 271 has a higher voltage than the second node 272). The latched output of the sense amplifier 270, corresponding to the detected logic state of memory cell 105-a, may be output via one or more input/output (I/O) lines (e.g., I/O line 275), which may include an output through a column component 135 or an input/output component 160 described with reference to FIG. 1.

To perform a write operation on the memory cell 105-a, a voltage may be applied across the capacitor 220 by controlling the voltage of the cell plate 221 (e.g., through the plate line 140-a) and the cell bottom 222 (e.g., through the digit line 130-a). For example, to write a logic 0, the cell plate 221 may be taken low (e.g., grounding the plate line 140-a, virtually grounding the plate line 140-a, applying a negative voltage to the plate line 140-a), and the cell bottom 222 may be taken high (e.g., applying a positive voltage to the digit line 130-a). The opposite process may be performed to write a logic 1, where the cell plate 221 is taken high and the cell bottom 222 is taken low. In some cases, the voltage applied across the capacitor 220 during a write operation may have a magnitude equal to or greater than a saturation voltage of a ferroelectric material in the capacitor 220, such that the capacitor 220 is polarized, and thus maintains a charge even when the magnitude of applied voltage is reduced, or if a zero net voltage is applied across the capacitor 220.

The circuit 200, including the sense amplifier 270, the cell selection component 230, the signal development component 260, or the reference component 280, may include various types of transistors. For example, the circuit 200 may include n-type transistors, where applying a relative positive voltage to the gate of the n-type transistor that is above a threshold voltage for the n-type transistor (e.g., an applied voltage having a positive magnitude, relative to a source terminal, that is greater than a threshold voltage) enables a conductive path between the other terminals of the n-type transistor (e.g., a drain terminal and the source terminal, across a conduction channel).

In some examples, the n-type transistor may act as a switching component, where the applied voltage is a logical signal that is used to enable conductivity through the transistor by applying a relatively high logical signal voltage (e.g., a voltage corresponding to a logic 1 state, which may be associated with a positive logical signal voltage supply), or to disable conductivity through the transistor by applying a relatively low logical signal voltage (e.g., a voltage corresponding to a logic 0 state, which may be associated with a ground or virtual ground voltage). In some examples where a n-type transistor is employed as a switching component, the voltage of a logical signal applied to the gate terminal may be selected to operate the transistor at a particular working point (e.g., in a saturation region or in an active region).

Additionally, or alternatively, the circuit 200 may include p-type transistors, where applying a relative negative voltage to the gate of the p-type transistor that is above a threshold voltage for the p-type transistor (e.g., an applied voltage having a negative magnitude, relative to a source terminal, that is greater than a threshold voltage) enables a conductive path between the other terminals of the p-type transistor (e.g., a drain terminal and the source terminal, across a conductive channel).

In some examples, the p-type transistor may act as a switching component, where the applied voltage is a logical signal that is used to enable conductivity by applying a relatively low logical signal voltage (e.g., a voltage corresponding to a logical “1” state, which may be associated with a negative logical signal voltage supply), or to disable conductivity by applying a relatively high logical signal voltage (e.g., a voltage corresponding to a logical “0” state, which may be associated with a ground or virtual ground voltage). In some examples where a p-type transistor is employed as a switching component, the voltage of a logical signal applied to the gate terminal may be selected to operate the transistor at a particular working point (e.g., in a saturation region or in an active region).

A transistor of the circuit 200 may be a field-effect transistor (FET), including a metal oxide semiconductor FET, which may be referred to as a MOSFET. In some examples, these and other types of transistors may be formed by doped regions of material of a substrate. In some examples, the transistor(s) may be formed on a substrate that is dedicated to a particular component of the circuit 200 (e.g., a substrate for the sense amplifier 270, a substrate for the signal development component 260, a substrate for the reference component 280, a substrate for the memory cell 105-a), or the transistor(s) may be formed on a substrate that is common for particular components of the circuit 200 (e.g., a substrate that is common to two or more of the sense amplifier 270, the signal development component 260, the reference component 280, or the memory cell 105-a). Some FETs may have a metal portion including aluminum or other metal, but some FETs may implement other non-metal materials such as polycrystalline silicon, including those FETs that may be referred to as a MOSFET. Further, although an oxide portion may be used as a dielectric portion of a FET, other non-oxide materials may be used in a dielectric material in a FET, including those FETs that may be referred to as a MOSFET.

Although the circuit 200 illustrates a set of components relative to a single memory cell 105, various components of the circuit 200 may be duplicated in a memory device 100 to support various operations. For example, to support row access or page access operations, a sense component 150 may be configured with multiples of one or more of a signal development component 260, a signal line 265, a reference component 280, a reference line 285, a sense amplifier 270, or other components, where the multiples may be configured according to a quantity of memory cells 105 that may be accessed in a row access or page access operation (e.g., in a concurrent operation).

In some examples, capacitance 240 may be a significant contribution to power consumption, latency, or both when accessing the memory cell 105-a. For example, a substantial amount of power consumption associated with reading, writing, or refreshing the memory cell 105-a may be associated with digit line charging current, which may be a function of the capacitance 240. The capacitance 240 may be a function of the length of the digit line 130-a, which may be associated with a quantity of rows (e.g., word lines 120 in addition to the word line 120-a) that intersect the digit line 130-a. As memory arrays become larger, more dense, or both, a quantity of rows that intersect the digit line 130-a may increase, which thus may be associated with power consumption, latency, or other concerns.

In accordance with aspects as disclosed herein, the circuit 200 may include a transistor (e.g., a multiplexor, a pass gate) that divides (e.g., bisects) the digit line 130-a into a first address range (e.g., associated with a first range of word lines 120 that includes the word line 120-a) and a second address range (e.g., associated with a second range of word lines 120 different from the word line 120-a), which may be associated with a division along a length of the digit line 130-a. Dividing the digit line 130-a may divide the capacitance 240 into the different portions (e.g., a first portion of the capacitance 240 associated with the first address range, a second portion of the capacitance 240 associated with the second address range), which may reduce the effective capacitance of accessing at least a portion of the digit lines 130, thereby reducing an amount of power used to access at least some memory cells 105. For example, a first portion of the capacitance 240, associated with a first portion of the digit line 130-a, may be coupled with the sense component 150-a (e.g., while accessing the memory cell 105-a), whereas a second portion of the capacitance 240, associated with a second portion of the digit line 130-a, may be isolated from the sense component 150-a. By reducing effective capacitance of the digit line 130-a that is coupled with the sense component 150-a while accessing at least the memory cell 105-a, the described techniques may support reduced power consumption, reduced latency, or both.

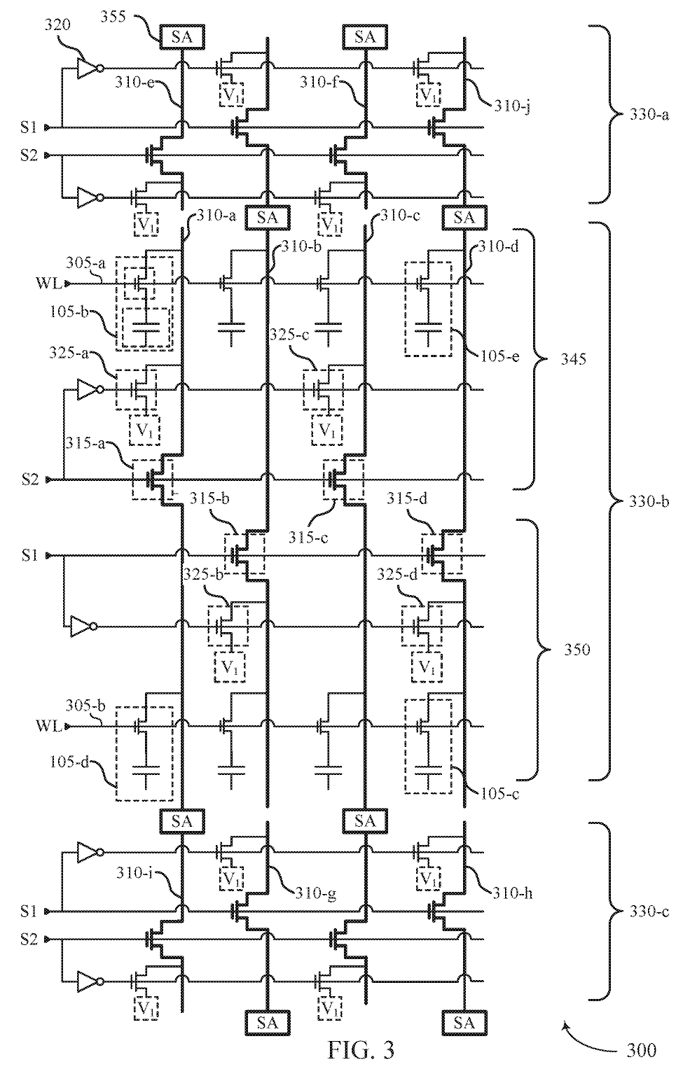

FIG. 3 shows an example of a circuit 300 that supports access line division for memory devices in accordance with examples as disclosed herein. The circuit 300 may include one or more sections 330 (e.g., of word lines 305, of digit lines 310, mats of memory cells 105). For example, the circuit 300 illustrates an example that includes sections 330-a, 330-b, and 330-c. For examples in which a memory cell 105 (e.g., memory cell 105-b, memory cell 105-c) of the section 330-b is being accessed, the section 330-b may be referred to as an active section and the sections 330-a and 330-c may each be referred to as a reference section. However, in some other examples, such nomenclature may be different. For example, if a memory cell 105 of the section 330-a is being accessed, then the section 330-a may be referred to as an active section and the section 330-b may be referred to as a reference section or, if a memory cell 105 of the section 330-c is being accessed, then the section 330-c may be referred to as an active section and the section 330-b may be referred to as a reference section. Although the illustrated example includes three sections, a circuit 300 (e.g., a memory bank) in accordance with the described techniques may include any quantity of one or more sections 330.

Each of the sections 330 may include multiple access lines. For example, the sections 330 may include word lines 305 (e.g., a word line 305-a and a word line 305-b of section 330-b) and digit lines 310 (e.g., digit lines 310-a, 310-b, 310-c, and 310-d of section 330-b), which may be examples of the word lines 120 and digit lines 130, respectively. Each word line 305 may be operable to couple multiple memory cells 105 with the digit lines 310 (e.g., word line 305-a may be activated to couple a memory cell 105-b with a digit line 310-a, word line 305-b may be activated to couple a memory cell 105-c with a digit line 310-d). Each digit line 310 may be operable to couple with a respective sense amplifier (SA) 355 (e.g., operable to sense a state of a coupled memory cell 105), which may be an example of a sense amplifier 270. Although sections 330-a and 330-c are not illustrated with word lines 305 and memory cells 105, in various examples, sections 330-a and 330-c may include word lines 305 and memory cells 105 in a similar arrangement as section 330-b, or in a different arrangement, or may omit word lines 305 and memory cells 105. Further, each section 330 may include any quantity of one or more word lines 305 and any quantity of one or more digit lines 310.

In some examples, the circuit 300 (e.g., each section 330) may include a first set of digit lines 310 (e.g., a set of even digit lines) and a second set of digit lines 310 (e.g., a set of odd digit lines). For example, digit lines 310-a and 310-c may be even digit lines 310 of the section 330-b, and digit lines 310-b and 310-d may be odd digit lines 310 of the section 330-b. Each set of even digit lines 310 and each set of odd digit lines 310 may correspond to a respective set of sense amplifiers 355. For example, a set of even digit lines 310 of the section 330-b may be coupled with sense amplifiers 355 shared by the section 330-b and the reference section 330-c, and a set of odd digit lines 310 of the section 330-b may be coupled with the sense amplifiers 355 shared by the section 330-b and the section 330-a. Memory cells 105 accessed along a respective digit line 310 may be sensed using the sense amplifier 355 coupled with the respective digit line 310.

During access of a memory cell 105 that is located in one section 330 (e.g., memory cell 105-b, memory cell 105-c, of section 330-b), a reference voltage bias, a reference capacitance, or both, may be provided to one or more of the sense amplifiers 355 by another adjacent section 330 (e.g., by the section 330-a, the section 330-c, or both). For example, target digit lines 310 (e.g., of an active section 330) may each correspond to a signal line 265, and digit lines 310 on an opposite side of a sense amplifier 355 from the section 330-b (e.g., digit lines 310 in the sections 330-a and 330-c) may each correspond to a reference line 285, and may be referred to as a reference digit line. During a sensing operation, for example, the reference digit lines 310 (e.g., nodes 272) may be biased with a voltage, V₁. (e.g., as an example of V_{ref}). In some examples, V₁ may be a plate voltage of the circuit 300 (e.g., V₁may be half of the power supply voltage of the circuit 300). Additionally, or alternatively, the voltage V₁ may be applied internally to a respective sense amplifier 355 (e.g., at a node 272). In some examples, a capacitance of each of the reference digit lines 310 in the sections 330-a and 330-c (e.g., as observed at respective nodes 272) may be configured to be the same (or substantially the same) as a capacitance of each of the digit lines 310 in the section 330-b (e.g., as observed at respective nodes 271). For example, the sense amplifiers 355 coupled with the section 330-b may sense a state of a respective memory cell 105 of the section 330-b based on the voltage V₁ and the matching (or substantially matching) capacitance of the digit lines 310 of the section 330-b and the reference digit lines 310 of the sections 330-a and 330-c.

The circuit 300 may perform access operations (e.g., read operations, write operations, refresh operations) on one or more memory cells 105 by activating one or more word lines 305 and one or more digit lines 310 coupled with the one or more memory cells 105. In some memory devices an amount of power used to perform access operations (e.g., for access line selection, for access line biasing) may increase with a quantity of memory cells in a given implementation (e.g., along a given word line, along a given digit line, or both). In some examples, a majority of the power used to perform an access operation may be based on a digit line charging current (e.g., an amount of current to charge the digit line to a given voltage), which may be a function of digit line capacitance.

In accordance with examples as described herein, the circuit 300 may include transistors 315 (e.g., as n-type transistors or p-type transistors) coupled with (e.g., along) each of the digit lines 310 that support reducing power used to activate the digit lines 310 compared to other memory devices. The transistors 315 may divide (e.g., bisect, across a channel of the transistors 315) the digit lines 310 (e.g., in the sections 330-a, 330-b, and 330-c), which may reduce a capacitance of the digit lines 310 (e.g., as observed by the sense amplifiers 355, as a reduction of capacitance observed at nodes 271 and 272, by isolating at least a portion of a capacitance 240 from the sense amplifiers 355), and reduce an amount of power used to charge or activate a respective digit line 310. For example, the section 330-b may include a range 345 (e.g., a first row of address range, a first range of word lines 305, a first digit line length) and a range 350 (e.g., a second range of row addresses, a second range of word lines 305, a second digit line length) based on the transistors 315 dividing the digit lines 310. In some examples, the transistors 315 may be positioned equidistant between the sense amplifiers 355 coupled with the section 330-a and the sense amplifiers 355 coupled with the reference section 330-c. Additionally, or alternatively, the section 330-a and the section 330-c may include transistors 315 positioned equidistant between the stripes of sense amplifiers 355.

The transistors 315 may be operable to couple a first portion of a respective digit line 310 (e.g., a portion corresponding to the range 345) with a second portion of the respective digit line 310 (e.g., a portion corresponding to the range 350). In some examples (e.g., in a planar array implementation), the respective portions of a digit line 310 that are coupled via a transistor 315 may be different portions along a direction over (e.g., parallel to) a semiconductor substrate (e.g., portions coupled via transistors 315 that are formed in part by a doped portion of the semiconductor substrate, portions of digit lines 310 in a common layer over the semiconductor substrate). In some other examples (e.g., in a three-dimensional array implementation), the respective portions of a digit line 310 that are coupled via a transistor 315 may be different portions along a direction from (e.g., perpendicular to) a semiconductor substrate (e.g., coupled by vertical transistors 315 that are formed above the semiconductor substrate, portions of digit lines 310 at different heights from the semiconductor substrate). In some examples, half of the word lines 305 of the section 330-b may be in the range 345 and the other half may be in the range 350. For example, range 345 may include word line 305-a and range 350 may include word line 305-b. Although two word lines 305 (e.g., word line 305-a and word line 305-b) are shown in the illustrative example of section 330-b, it is to be understood that the circuit 300 may implement any quantity of word lines 305 in a given range 345 and in a given range 350. For example, the section 330-b may include one thousand or more word lines 305 (e.g., with half in the range 345 and half in the range 350).

The circuit 300 may also include transistors 325 (e.g., as n-type transistors or p-type transistors). The transistors 325 may each have a channel (e.g., a semiconductor path) operable to bias a portion of a respective digit line 310. A portion of a digit line 310 for which a respective transistor 325 biases may be based on whether the transistor 325 is coupled with an even digit line 310 (e.g., a digit line 310 from among the set of even digit lines 310) or an odd digit line 310 (e.g., a digit line 310 from among the set of odd digit lines 310). If the transistor 325 is coupled with an even digit line 310, such as the digit line 310-a, the transistor 325 may be operable to bias the first portion (e.g., the portion of the digit line 310-a in the range 345 and above the transistor 315-a, with the voltage V₁). If the transistor 325 is coupled with an odd digit line 310, such as the digit line 310-b, the transistor 325 may be operable to bias the second portion (e.g., the portion of the digit line 310-b in the range 350 and below the transistor 315-b, with the voltage V₁).

In some examples, a set of the transistors 325 (e.g., gates of transistors 325 of the set) may be coupled with a respective inverter 320. For example, each range of a given section 330 (e.g., ranges 345 and range 350 of section 330-b) may include a respective set of the transistors 325. Each set (e.g., row) of transistors 325 may be coupled with a respective inverter 320. Each of the inverters 320 may be configured to receive an activation signal (activation signal S1 or activation signal S2) and output an inversion of the activation signal to the transistors 325. In some examples, the transistors 315 may each include a gate operable to couple with the activation signal S1 or the activation signal S2, and each of the transistors 315 may couple the first portion with the second portion of a given digit line 310 based on the activation signals biasing a respective gate.

Memory cells 105 in the circuit 300 may be accessed based on selecting a target word line 305 (e.g., based on a row address of an activation command, such as an ACT command, from a host, based on a row address determined at the memory device 100 for a memory management operation, such as a self-refresh operation), a target digit line 310, and biasing the activation signals S1 and S2 (e.g., before activating a target word line 305). An amount of power used to access at least some of the memory cells 105 may be reduced relative to other techniques based on the transistors 315 segmenting (e.g., bisecting, isolating, dividing) at least one of the digit lines 310 (e.g., reducing a capacitance 240 of the at least one digit line 310). The circuit 300 may activate the target word line 305, digit line 310, and bias the activation signals S1 and S2 based on which range corresponds to a respective memory cell 105. For example, the memory cell 105-b may in the range 345 and memory cell 105-c may be in the range 350. In some examples, the circuit 300 (e.g., a controller of the circuit 300, a memory controller 170) may bias the activation signal S1 and the activation signal S2 before activating the target word line 305 or at substantially the same time as activating the target word line 305.

In a first example, to access the memory cell 105-b (e.g., of the range 345), the circuit 300 may activate word line 305-a and digit line 310-a. Based on the memory cell 105-b (e.g., word line 305-a) corresponding to the range 345, the circuit 300 may bias the activation signal S2 (e.g., an even digit line signal) to a first state (e.g., a logic high state) and, in some examples, may bias the activation signal S1 (e.g., an odd digit line signal) to a second state (e.g., a logic low state), which may include such biasing before activating the word line 305-a. Biasing the activation signal S2 to the first state may bias the gates of the transistors 315 coupled with even digit lines (e.g., the transistor 315-a and the transistor 315-c). The transistor 315-a may couple the first portion of the digit line 310-a (e.g., the portion including the memory cell 105-b) with the second portion of the digit line 310-a (e.g., the portion coupled with the sense amplifier 355) based on the gate being biased with the first state. The sense amplifier 355 coupled with the digit line 310-a may sense a state of the memory cell 105-b based on activating the word line 305-a and biasing the gate of the transistor 315-a. Biasing the activation signal S2 to the first state may result in the inverters 320 coupled with the activation signal S2 to output the second state to a subset of the transistors 325. For example, the gates of the transistors 325-a and 325-c may be biased with the second state. Biasing the gates of the transistors 325-a and 325-c may isolate the voltage V₁ from the row address range 345 (e.g., from the first portion of the digit line 310-a).

The activation signals S1 and S2 may also bias transistors 315 and 325 in the sections 330-a and 330-c such that a capacitance of the even digit lines 310 coupled with the sense amplifiers 355 in the section 330-b is substantially the same as the capacitance of the digit lines 310 (e.g., the reference digit lines) in each of the sections 330-a and 330-c. For example, the first state of the activation signal S2 may bias gates of the transistors 315 coupled with digit line 310-e and digit line 310-f (e.g., even digit lines in the section 330-a) and the transistors 315 coupled with the reference digit lines corresponding to digit lines 310-a and 310-c (e.g., even digit lines in the reference section 330-c). The inverters 320 in the section 330-a and the reference section 330-c coupled with the activation signal S2 may isolate the transistors 325 coupled with the even digit lines in the sections 330-a and 330-c. The second state of the activation signal S1 may bias the gates of the transistors 315 coupled with the odd digit lines (e.g., the reference digit lines corresponding to digit line 310-b and digit line 310-d) such that a portion of the odd digit lines in each of the sections 330-a and 330-c are isolated from the portion of the odd digit lines coupled with the sense amplifiers 355. Additionally, the inverters 320 coupled with the activation signal S1 may bias the transistors 325, which may result in the transistors 325 biasing the isolated portions with the voltage V₁.

Biasing the activation signal S1 to the second state may bias the gates of the transistors 315 coupled with odd digit lines (e.g., the transistor 315-b and the transistor 315-d). For example, the transistors 315-b and 315-d may isolate the portions of the odd digit lines (e.g., digit lines 310-b and 310-d) in the row address range 350 from the portions of the odd digit lines in the row address range 345. Biasing the activation signal S1 to the second state may also result in the inverters 320 coupled with the activation signal S1 to output the first state to a subset of the transistors 325. For example, the gates of the transistors 325-b and 325-d may be biased with the first state, which may bias the portions of the odd digit lines in the row address range 350 with the voltage V₁ (e.g., to prevent the isolated portions of the digit lines 310-b and 310-d from floating). In some other examples, the activation signal S1 may not be biased when accessing the memory cell 105-b, or may be held at a bias from a prior access operation, among other implementations.

In a second example, to access the memory cell 105-d (e.g., of the range 350), the circuit 300 may also activate digit line 310-a, but may alternatively activate word line 305-b. Based on the memory cell 105-d (e.g., word line 305-b) corresponding to the range 350, the circuit 300 may bias the activation signal S2 to the second state (e.g., a logic low state) and may, in some examples, also bias the activation signal S1 to the second state (e.g., a logic low state), which may include such biasing before activating the word line 305-b. Biasing the activation signal S2 to the second state may bias the gates of the transistors 315 coupled with even digit lines to isolate the first portion of the digit line 310-a (e.g., the portion associated with the range 345) from the second portion of the digit line 310-a (e.g., the portion coupled with the sense amplifier 355) based on the gate being biased with the second state. The sense amplifier 355 coupled with the digit line 310-a may sense a state of the memory cell 105-d based on activating the word line 305-b and biasing the gate of the transistor 315-a. Biasing the activation signal S2 to the second state may result in the inverters 320 coupled with the activation signal S2 to output the first state to a subset of the transistors 325. For example, the gates of the transistors 325-a and 325-c may be biased with the first state. Biasing the gates of the transistors 325-a and 325-c may couple the voltage V₁ with the range 345 (e.g., from the first portion of the digit line 310-a). In some examples, biasing the activation signal S2 to the second state (e.g., a logic low state) may also isolate a portion of the digit line 310-i of the section 330-c from the sense amplifier 355 coupled with the digit line 310-a, such that the capacitance of the digit line 310-i that is coupled with the sense amplifier 355 (e.g., at a node 272) can more closely match the portion of the digit line 310-a that is coupled with the sense amplifier 355 (e.g., at a node 271), such as the portion of digit line 310-a in the range 350 that is isolated from the portion of the digit line 310-a in the range 345. (e.g., isolating respective portions of capacitance 240 of each of the digit lines 310-a and 310-i).

In a third example, to access the memory cell 105-c, the circuit 300 may activate word line 305-b and digit line 310-d. Based on the memory cell 105-c corresponding to the range 345, the circuit 300 may bias the activation signal S1 (e.g., an odd digit line signal) to the first state (e.g., a logic high state) and may, in some examples, bias the activation signal S2 (e.g., an even digit line signal) to the second state (e.g., a logic low state), which may include such biasing before activating the word line 305-b. Biasing the activation signal S1 to the first state may bias the gates of the transistors 315 coupled with odd digit lines (e.g., the transistor 315-b and the transistor 315-d). The transistor 315-d may couple the first portion of the digit line 310-d (e.g., the portion coupled with the sense amplifier 355) with the second portion of the digit line 310-d (e.g., the portion including the memory cell 105-c). The sense amplifier 355 coupled with the digit line 310-d may sense a state of the memory cell 105-c based on activating the word line 305-b and biasing the gate of the transistor 315-d. Biasing the activation signal S1 to the first state may result in the inverters 320 coupled with the activation signal S1 to output the second state to a subset of the transistors 325. For example, the gates of the transistors 325-b and 325-d may be biased with the second state. Biasing the gates of the transistors 325-b and 325-d may isolate the voltage V₁ from the row address range 350 (e.g., from the second portion of the digit line 310-d). In some examples,

Biasing the activation signal S2 to the second state may bias the gates of the transistors 315 coupled with even digit lines (e.g., the transistor 315-a and the transistor 315-c). For example, the transistors 315-a and 315-c may isolate the portions of the even digit lines (e.g., digit lines 310-a and 310-c) in the row address range 345 from the portions of the even digit lines in the row address range 350. Biasing the activation signal S2 to the second state may also result in the inverters 320 coupled with the activation signal S2 to output the first state to a subset of the transistors 325. For example, the gates of the transistors 325-a and 325-c may be biased with the first state, which may bias the portions of the even digit lines in the row address range 345 with the voltage V₁(e.g., to prevent the isolated portions of the digit lines 310-a and 310-c from floating). In some other examples, the activation signal S2 may not be biased when accessing the memory cell 105-c, or may be held at a bias from a prior access operation, among other implementations.

The first state of the activation signal S1 may bias gates of the transistors 315 coupled with digit line 310-g and digit line 310-h (e.g., odd digit lines in the reference section 330-c) and the transistors 315 coupled with the reference digit lines corresponding to digit lines 310-b and 310-d (e.g., odd digit lines in the section 330-a). The inverters 320 in the reference section 330-a and the section 330-c coupled with the activation signal S1 may isolate the transistors 325 coupled with the odd digit lines in the sections 330-a and 330-c. The second state of the activation signal S2 may bias the gates of the transistors 315 coupled with the even digit lines (e.g., the reference digit lines corresponding to digit line 310-a and digit line 310-c) such that a portion of the even digit lines in each of the sections 330-a and 330-c are isolated from the portion of the even digit lines coupled with the sense amplifiers 355. Additionally, the inverters 320 coupled with the activation signal S2 may bias the transistors 325, which may result in the transistors 325 biasing the isolated portions with the voltage V₁.

In a fourth example, to access the memory cell 105-e (e.g., of the range 345), the circuit 300 may also activate digit line 310-d, but may alternatively activate word line 305-a. Based on the memory cell 105-e (e.g., word line 305-a) corresponding to the range 345, the circuit 300 may bias the activation signal S1 to the second state (e.g., a logic low state) and may, in some examples, also bias the activation signal S2 to the second state (e.g., a logic low state), which may include such biasing before activating the word line 305-a. Biasing the activation signal S1 to the second state may bias the gates of the transistors 315 coupled with odd digit lines to isolate the first portion of the digit line 310-a (e.g., the portion associated with the range 350) from the second portion of the digit line 310-d (e.g., the portion coupled with the sense amplifier 355) based on the gate being biased with the second state. The sense amplifier 355 coupled with the digit line 310-d may sense a state of the memory cell 105-e based on activating the word line 305-a and biasing the gate of the transistor 315-d. Biasing the activation signal S1 to the second state may result in the inverters 320 coupled with the activation signal S1 to output the first state to a subset of the transistors 325. For example, the gates of the transistors 325-d and 325-d may be biased with the first state. Biasing the gates of the transistors 325-b and 325-d may couple the voltage V₁with the range 350 (e.g., with the first portion of the digit line 310-d). In some examples, biasing the activation signal S1 to the second state (e.g., a logic low state) may also isolate a portion of the digit line 310-j of the section 330-a from the sense amplifier 355 coupled with the digit line 310-d, such that the capacitance of the digit line 310-j that is coupled with the sense amplifier 355 (e.g., at a node 272) can more closely match the portion of the digit line 310-d that is coupled with the sense amplifier 355 (e.g., at a node 271), such as the portion of digit line 310-d in the range 345 that is isolated from the portion of the digit line 310-d in the range 350. (e.g., isolating respective portions of capacitance 240 of each of the digit lines 310-d and 310-j).

In various examples of the techniques herein, at least a portion of a digit line 310 may be biased to the voltage V₁ (and not activated) to access the target memory cell 105. For example, the portion of the digit line 310-b coupled with the channel of the transistor 315-b in the row address range 350 may be biased to V₁ while accessing the memory cell 105-b and the portion of the digit line 310-c coupled with the channel of the transistor 315-c in the row address range 345 may be biased to V₁ while accessing the memory cell 105-c. In some examples, biasing shorter portions of a digit line 310 (e.g., of a target digit line 310, of a reference digit line 310, such as when accessing memory cells 105-d and 105-e) rather than an entire length of a digit line 310 to access a target memory cell 105 may reduce an amount of power or an amount of time used to access the target memory cell 105 (e.g., based on reducing an amount of capacitance 240 that is biased, based on reducing an amount of capacitance 240 that is coupled with access circuitry).

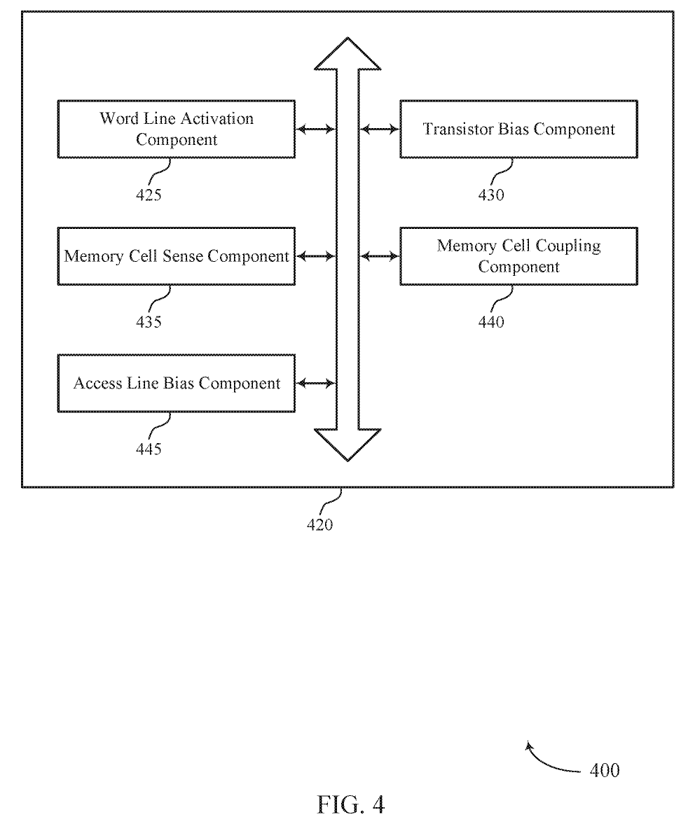

FIG. 4 shows a block diagram 400 of a memory device 420 that supports access line division for memory devices in accordance with examples as disclosed herein. The memory device 420 may be an example of aspects of a memory device as described with reference to FIGS. 1 through 3. The memory device 420, or various components thereof, may be an example of means for performing various aspects of access line division for memory devices as described herein. For example, the memory device 420 may include a word line activation component 425, a transistor bias component 430, a memory cell sense component 435, a memory cell coupling component 440, an access line bias component 445, or any combination thereof. Each of these components, or components of subcomponents thereof (e.g., one or more processors, one or more memories), may communicate, directly or indirectly, with one another (e.g., via one or more buses).

The word line activation component 425 (e.g., a portion of or coupled with a row component 125) may be configured as or otherwise support a means for activating a word line (e.g., a word line 120, a word line 305) of a memory array (e.g., a memory array 110). The transistor bias component 430 (e.g., a portion of or coupled with a row component 125, a column component 135, or both) may be configured as or otherwise support a means for biasing a gate of a transistor (e.g., a transistor 315) based at least in part on whether activating the word line couples a memory cell (e.g., a memory cell 105) with a first portion of an access line (e.g., a digit line 130) of the memory array or a second portion of the access line, the first portion of the access line operable to couple with a sense amplifier (e.g., a sense amplifier 270, a sense amplifier 355, of a sense component 150) and the second portion of the access line operable to couple with the first portion via a channel of the transistor. The memory cell sense component 435 (e.g., of or coupled with a sense component 150, a sense amplifier 270, a sense amplifier 355) may be configured as or otherwise support a means for sensing, using the sense amplifier, a state of the memory cell based at least in part on activating the word line and biasing the gate of the transistor. In some examples, the second portion of the access line is operable to couple with the sense amplifier via the first portion of the access line.

In some examples, the memory cell coupling component 440 (e.g., of or coupled with a cell selection component 230) may be configured as or otherwise support a means for coupling the memory cell (e.g., coupling a capacitor 220 of the memory cell) with the first portion of the access line based at least in part on activating the word line, the first portion of the access line being isolated from the second portion of the access line based at least in part on biasing the gate of the transistor. In some examples, the access line bias component 445 may be configured as or otherwise support a means for biasing the second portion of the access line with a voltage (e.g., a voltage V1, via a transistor 325) based at least in part on coupling the memory cell with the first portion of the access line and isolating the first portion of the access line from the second portion of the access line.

In some examples, the transistor bias component 430 may be configured as or otherwise support a means for biasing a second gate of a second transistor (e.g., a second transistor 315) based at least in part on coupling the memory cell with the first portion of the access line, where biasing the second gate of the second transistor isolates a second portion of a second access line (e.g., of a second digit line 130) from a first portion of the second access line, where sensing the state of the memory cell is based at least in part on the first portion of the second access line being coupled with the sense amplifier and the second portion of the second access line being isolated from the first portion of the second access line.

In some examples, the memory cell coupling component 440 may be configured as or otherwise support a means for coupling the memory cell with the second portion of the access line based at least in part on activating the word line, the first portion of the access line being coupled with the second portion of the access line based at least in part on biasing the gate of the transistor. In some examples, the transistor bias component 430 may be configured as or otherwise support a means for biasing a second gate of a second transistor (e.g., a second transistor 315) based at least in part on coupling the memory cell with the second portion of the access line, where biasing the second gate of the second transistor couples a second portion of a second access line (e.g., a second digit line 130) with a first portion of the second access line, where sensing the state of the memory cell is based at least in part on the second portion of the second access line being coupled with the sense amplifier via the first portion of the second access line.

In some examples, the first portion is associated with a first address range (e.g., a first range of word lines 120, a range 345) and the second portion is associated with a second address range (e.g., a second range of word lines 120, a range 350). In some examples, activating the word line to couple the memory cell with the first portion or the second portion is based at least in part on an address of the memory cell being in the first address range of the second address range.

In some examples, the described functionality of the memory device 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory device 420, or various components thereof, may be implemented at least in part by instructions (e.g., stored in memory, non-transitory computer-readable medium) executable by such at least one processor.

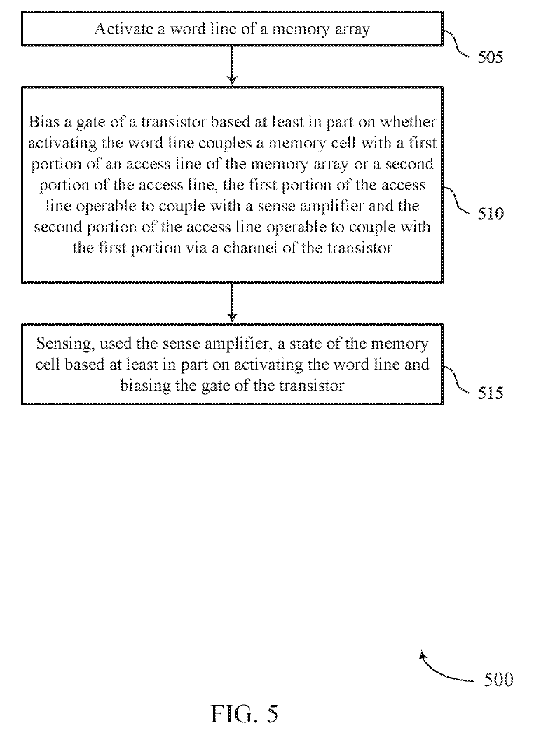

FIG. 5 shows a flowchart illustrating a method 500 that supports access line division for memory devices in accordance with examples as disclosed herein. The operations of method 500 may be implemented by a memory device or its components as described herein. For example, the operations of method 500 may be performed by a memory device as described with reference to FIGS. 1 through 4. In some examples, a memory device may execute a set of instructions to control the functional elements of the device to perform the described functions. Additionally, or alternatively, the memory device may perform aspects of the described functions using special-purpose hardware.

At 505, the method may include activating a word line of a memory array. In some examples, aspects of the operations of 505 may be performed by a word line activation component 425 as described with reference to FIG. 4.

At 510, the method may include biasing a gate of a transistor based at least in part on whether activating the word line couples a memory cell with a first portion of an access line of the memory array or a second portion of the access line, the first portion of the access line operable to couple with a sense amplifier and the second portion of the access line operable to couple with the first portion via a channel of the transistor. In some examples, aspects of the operations of 510 may be performed by a transistor bias component 430 as described with reference to FIG. 4.

At 515, the method may include sensing, using the sense amplifier, a state of the memory cell based at least in part on activating the word line and biasing the gate of the transistor. In some examples, aspects of the operations of 515 may be performed by a memory cell sense component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for activating a word line of a memory array; biasing a gate of a transistor based at least in part on whether activating the word line couples a memory cell with a first portion of an access line of the memory array or a second portion of the access line, the first portion of the access line operable to couple with a sense amplifier and the second portion of the access line operable to couple with the first portion via a channel of the transistor; and sensing, using the sense amplifier, a state of the memory cell based at least in part on activating the word line and biasing the gate of the transistor.

Aspect 2: The method, apparatus, or non-transitory computer-readable medium of aspect 1, where the second portion of the access line is operable to couple with the sense amplifier via the first portion of the access line.

Aspect 3: The method, apparatus, or non-transitory computer-readable medium of any of aspects 1 through 2, further including operations, features, circuitry, logic, means, or instructions, or any combination thereof for coupling the memory cell with the first portion of the access line based at least in part on activating the word line, the first portion of the access line being isolated from the second portion of the access line based at least in part on biasing the gate of the transistor.

Aspect 4: The method, apparatus, or non-transitory computer-readable medium of aspect 3, further including operations, features, circuitry, logic, means, or instructions, or any combination thereof for biasing the second portion of the access line with a voltage based at least in part on coupling the memory cell with the first portion of the access line and isolating the first portion of the access line from the second portion of the access line.

Aspect 5: The method, apparatus, or non-transitory computer-readable medium of any of aspects 3 through 4, further including operations, features, circuitry, logic, means, or instructions, or any combination thereof for biasing a second gate of a second transistor based at least in part on coupling the memory cell with the first portion of the access line, where biasing the second gate of the second transistor isolates a second portion of a second access line from a first portion of the second access line, where sensing the state of the memory cell is based at least in part on the first portion of the second access line being coupled with the sense amplifier and the second portion of the second access line being isolated from the first portion of the second access line.

Aspect 6: The method, apparatus, or non-transitory computer-readable medium of any of aspects 1 through 5, further including operations, features, circuitry, logic, means, or instructions, or any combination thereof for coupling the memory cell with the second portion of the access line based at least in part on activating the word line, the first portion of the access line being coupled with the second portion of the access line based at least in part on biasing the gate of the transistor.

Aspect 7: The method, apparatus, or non-transitory computer-readable medium of aspect 6, further including operations, features, circuitry, logic, means, or instructions, or any combination thereof for biasing a second gate of a second transistor based at least in part on coupling the memory cell with the second portion of the access line, where biasing the second gate of the second transistor couples a second portion of a second access line with a first portion of the second access line, where sensing the state of the memory cell is based at least in part on the second portion of the second access line being coupled with the sense amplifier via the first portion of the second access line.

Aspect 8: The method, apparatus, or non-transitory computer-readable medium of any of aspects 1 through 7, where the first portion is associated with a first address range and the second portion is associated with a second address range and activating the word line to couple the memory cell with the first portion or the second portion is based at least in part on an address of the memory cell being in the first address range of the second address range.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:

Aspect 9: A memory device, including: a plurality of access lines each operable to couple with a respective sense amplifier of a plurality of sense amplifiers; a plurality of word lines operable to couple a plurality of memory cells with the plurality of access lines; a plurality of first transistors each having a respective first channel operable to couple a first portion of a respective first access line of the plurality of access lines with a second portion of the respective first access line, and each having a respective first gate operable to couple with a first activation signal; and a plurality of second transistors each having a respective second channel operable to couple a first portion of a respective second access line of the plurality of access lines with a second portion of the respective second access line, and each having a respective second gate operable to couple with a second activation signal.

Aspect 10: The memory device of aspect 9, where: each first portion of a respective first access line is operable to couple with a respective first sense amplifier of the plurality of sense amplifiers via the second portion of the respective first access line; and each second portion of a respective second access line is operable to couple with a respective second sense amplifier of the plurality of sense amplifiers via the first portion of the respective second access line.

Aspect 11: The memory device of any of aspects 9 through 10, where: the first portions of the first access lines and the first portions of the second access lines are associated with a first set of the plurality of word lines, and the second portions of the first access lines and the second portions of the second access lines are associated with a second set of the plurality of word lines.

Aspect 12: The memory device of aspect 11, where: the first activation signal is configured to be activated in accordance with an activation of one or more of the first set of the plurality of word lines; and the second activation signal is configured to be activated in accordance with an activation of one or more of the second set of the plurality of word lines.

Aspect 13: The memory device of any of aspects 9 through 12, where: a first set of the plurality of word lines is operable to couple first memory cells of the plurality of memory cells with the first portions of the first access lines and the first portions of the second access lines; and a second set of the plurality of word lines is operable to couple second memory cells of the plurality of memory cells with the second portions of the first access lines and the second portions of the second access lines.

Aspect 14: The memory device of any of aspects 9 through 13, further including: a second plurality of access lines, a first set of the second plurality of access lines operable to couple with a respective sense amplifier of the plurality of sense amplifiers and a second set of the second plurality of access lines operable to couple with a respective sense amplifier of a second plurality of sense amplifiers; a plurality of third transistors, each of the plurality of third transistors having a respective third channel operable to couple a first portion of a respective third access line of the first set of the second plurality of access lines with a second portion of the respective third access line, and each of the plurality of third transistors having a respective third gate operable to couple with the second activation signal; and a plurality of fourth transistors, each of the plurality of fourth transistors having a respective third channel operable to couple with a first portion of a respective fourth access line of the second set of the second plurality of access lines with a second portion of the respective fourth access line, and each of the plurality of fourth transistors having a respective fourth gate operable to couple with the first activation signal.

Aspect 15: The memory device of aspect 14, where the first activation signal is applied to the first gates of the plurality of first transistors and the fourth gates of the plurality of fourth transistors and the second activation signal is applied to the second gates of the plurality of second transistors and the third gates of the plurality of third transistors.

Aspect 16: The memory device of any of aspects 9 through 15, further including: a plurality of fifth transistors, each of the plurality of fifth transistors having a respective fifth channel operable to bias the first portion of the respective first access line of the plurality of access lines based at least in part on the second activation signal, and each of the plurality of fifth transistors having a respective fifth gate operable to couple with a third activation signal; and a plurality of sixth transistors, each of the plurality of sixth transistors having a respective sixth channel operable to bias the second portion of the respective second access line of the plurality of access lines based at least in part on the first activation signal, and each of the plurality of sixth transistors having a respective sixth gate operable to couple with a fourth activation signal.

Aspect 17: The memory device of aspect 16, further including: a first inverter configured to receive the first activation signal and output the third activation signal as an inversion of the first activation signal; and a second inverter configured to receive the second activation signal and output the fourth activation signal as an inversion of the second activation signal.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor’s threshold voltage is applied to the transistor gate. The transistor may be “off” or “deactivated” when a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a plurality of access lines each operable to couple with a respective sense amplifier of a plurality of sense amplifiers;
a plurality of word lines operable to couple a plurality of memory cells with the plurality of access lines;
a plurality of first transistors each having a respective first channel operable to couple a first portion of a respective first access line of the plurality of access lines with a second portion of the respective first access line, and each having a respective first gate operable to couple with a first activation signal; and
a plurality of second transistors each having a respective second channel operable to couple a first portion of a respective second access line of the plurality of access lines with a second portion of the respective second access line, and each having a respective second gate operable to couple with a second activation signal.

2. The memory device of claim 1, wherein:
each first portion of a respective first access line is operable to couple with a respective first sense amplifier of the plurality of sense amplifiers via the second portion of the respective first access line; and
each second portion of a respective second access line is operable to couple with a respective second sense amplifier of the plurality of sense amplifiers via the first portion of the respective second access line.

3. The memory device of claim 1, wherein:
the first portions of the first access lines and the first portions of the second access lines are associated with a first set of the plurality of word lines, and
the second portions of the first access lines and the second portions of the second access lines are associated with a second set of the plurality of word lines.

4. The memory device of claim 3, wherein:
the first activation signal is configured to be activated in accordance with an activation of one or more of the first set of the plurality of word lines; and
the second activation signal is configured to be activated in accordance with an activation of one or more of the second set of the plurality of word lines.

5. The memory device of claim 1, wherein:
a first set of the plurality of word lines is operable to couple first memory cells of the plurality of memory cells with the first portions of the first access lines and the first portions of the second access lines; and
a second set of the plurality of word lines is operable to couple second memory cells of the plurality of memory cells with the second portions of the first access lines and the second portions of the second access lines.

6. The memory device of claim 1, further comprising:
a second plurality of access lines, a first set of the second plurality of access lines operable to couple with a respective sense amplifier of the plurality of sense amplifiers and a second set of the second plurality of access lines operable to couple with a respective sense amplifier of a second plurality of sense amplifiers;
a plurality of third transistors, each of the plurality of third transistors having a respective third channel operable to couple a first portion of a respective third access line of the first set of the second plurality of access lines with a second portion of the respective third access line, and each of the plurality of third transistors having a respective third gate operable to couple with the second activation signal; and
a plurality of fourth transistors, each of the plurality of fourth transistors having a respective third channel operable to couple with a first portion of a respective fourth access line of the second set of the second plurality of access lines with a second portion of the respective fourth access line, and each of the plurality of fourth transistors having a respective fourth gate operable to couple with the first activation signal.

7. The memory device of claim 6, wherein the first activation signal is applied to the first gates of the plurality of first transistors and the fourth gates of the plurality of fourth transistors and the second activation signal is applied to the second gates of the plurality of second transistors and the third gates of the plurality of third transistors.

8. The memory device of claim 1, further comprising:
a plurality of fifth transistors, each of the plurality of fifth transistors having a respective fifth channel operable to bias the first portion of the respective first access line of the plurality of access lines based at least in part on the second activation signal, and each of the plurality of fifth transistors having a respective fifth gate operable to couple with a third activation signal; and
a plurality of sixth transistors, each of the plurality of sixth transistors having a respective sixth channel operable to bias the second portion of the respective second access line of the plurality of access lines based at least in part on the first activation signal, and each of the plurality of sixth transistors having a respective sixth gate operable to couple with a fourth activation signal.

9. The memory device of claim 8, further comprising:
a first inverter configured to receive the first activation signal and output the third activation signal as an inversion of the first activation signal; and
a second inverter configured to receive the second activation signal and output the fourth activation signal as an inversion of the second activation signal.

10. A method, comprising:
activating a word line of a memory array;
biasing a gate of a transistor based at least in part on whether activating the word line couples a memory cell with a first portion of an access line of the memory array or a second portion of the access line, the first portion of the access line operable to couple with a sense amplifier and the second portion of the access line operable to couple with the first portion via a channel of the transistor; and
sensing, using the sense amplifier, a state of the memory cell based at least in part on activating the word line and biasing the gate of the transistor.

11. The method of claim 10, wherein the second portion of the access line is operable to couple with the sense amplifier via the first portion of the access line.

12. The method of claim 10, further comprising:
coupling the memory cell with the first portion of the access line based at least in part on activating the word line, the first portion of the access line being isolated from the second portion of the access line based at least in part on biasing the gate of the transistor.

13. The method of claim 12, further comprising:
biasing the second portion of the access line with a voltage based at least in part on coupling the memory cell with the first portion of the access line and isolating the first portion of the access line from the second portion of the access line.

14. The method of claim 12, further comprising:
biasing a second gate of a second transistor based at least in part on coupling the memory cell with the first portion of the access line, wherein biasing the second gate of the second transistor isolates a second portion of a second access line from a first portion of the second access line, wherein sensing the state of the memory cell is based at least in part on the first portion of the second access line being coupled with the sense amplifier and the second portion of the second access line being isolated from the first portion of the second access line.

15. The method of claim 10, further comprising:
coupling the memory cell with the second portion of the access line based at least in part on activating the word line, the first portion of the access line being coupled with the second portion of the access line based at least in part on biasing the gate of the transistor.

16. The method of claim 15, further comprising:
biasing a second gate of a second transistor based at least in part on coupling the memory cell with the second portion of the access line, wherein biasing the second gate of the second transistor couples a second portion of a second access line with a first portion of the second access line, wherein sensing the state of the memory cell is based at least in part on the second portion of the second access line being coupled with the sense amplifier via the first portion of the second access line.

17. The method of claim 10, wherein:
the first portion is associated with a first address range and the second portion is associated with a second address range, and
activating the word line to couple the memory cell with the first portion or the second portion is based at least in part on an address of the memory cell being in the first address range of the second address range.

18. A memory device, comprising:
a memory array; and
circuitry coupled with the memory array and configured to cause the memory device to:
activate a word line of the memory array;
bias a gate of a transistor based at least in part on whether activating the word line couples a memory cell with a first portion of an access line of the memory array or a second portion of the access line, the first portion of the access line operable to couple with a sense amplifier and the second portion of the access line operable to couple with the first portion via a channel of the transistor; and
sense, using the sense amplifier, a state of the memory cell based at least in part on activating the word line and biasing the gate of the transistor.

19. The memory device of claim 18, wherein circuitry is further configured to cause the memory device to:
couple the memory cell with the first portion of the access line based at least in part on activating the word line, the first portion of the access line being isolated from the second portion of the access line based at least in part on biasing the gate of the transistor.

20. The memory device of claim 19, wherein the circuitry is configured to cause the memory device to:
bias the second portion of the access line with a voltage based at least in part on coupling the memory cell with the first portion of the access line and isolating the first portion of the access line from the second portion of the access line.
